(19) United States
(12) Patent Application Publication
(10) Pub. No.: US 2025/0104911 A1
(43) Pub. Date: Mar. 27, 2025

(54) COAXIAL METAL INDUCTOR LOOPS AND ASSOCIATED METHODS

(71) Applicant: Intel Corporation, Santa Clara, CA (US)

(72) Inventors: Jaeil Baek, Chandler, AZ (US); Brandon Christian Marin, Gilbert, AZ (US); Beomseok Choi, Chandler, AZ (US); Kaladhar Radhakrishnan, Chandler, AZ (US)

(21) Appl. No.: 18/474,735

(22) Filed: Sep. 26, 2023

(51) Int. Cl. H01F 41/04; H01L 23/498; H01L 23/64

(52) U.S. Cl. CPC H01F 41/046; H01L 23/49822; H01L 23/49827; H01L 23/645

(57) ABSTRACT

Coaxial metal inductor loops and associated methods are disclosed. An example apparatus includes a substrate, first conductive material disposed along a first hole extending through the substrate, second conductive material disposed along a second hole extending through the substrate, and a magnetic material defining a continuous path completely encompassing both the first conductive material and the second conductive material in a plane perpendicular to an axis of the first hole.

### FIELD OF THE DISCLOSURE

This disclosure relates generally to electronic devices and, more particularly, to coaxial metal inductor loops and associated methods.

### BACKGROUND

Integrated circuit (IC) packages typically include one or more semiconductor dies supported on a package substrate. Efficient power management is an important consideration in IC package design. One approach to achieve efficient power management in IC packages is through the integration of voltage regulators directly into the semiconductor dies. Some such voltage regulators rely on capacitors and/or inductors contained in the IC package. Capacitors and/or inductors to be used by on-die voltage regulators may be embedded in the package substrates of associated IC packages.

### BRIEF DESCRIPTION OF THE DRAWINGS

FIG. 1 illustrates an example integrated circuit package constructed in accordance with teaching disclosed herein.

FIG. 2 is a cross-sectional side view of an example implementation of the example inductor of FIG. 1.

FIG. 3 is a cross-sectional top view of the example inductor of FIG. 2 taken along the line 3-3 in FIG. 2.

FIG. 4 is an isometric view of the example inductor of FIGS. 2 and 3 positioned adjacent to another example inductor.

FIGS. 5-8 illustrate alternative implementations of the example magnetic material of FIGS. 2-4.

FIG. 9 is a cross-sectional side view of another example implementation of the example inductor of FIG. 1.

FIG. 10 is a cross-sectional top view of the example inductor of FIG. 9 taken along the line 10-10 in FIG. 9.

FIG. 11 is an isometric view of the example inductor of FIGS. 9 and 10 positioned adjacent to another example inductor.

FIGS. 12-25 illustrate different example stages in a fabrication process for the example inductor of FIGS. 2-4 and/or any of the variations detailed in connection with FIGS. 5-8.

FIGS. 26-29 illustrate different example stages in a fabrication process for the example inductor of FIGS. 9-11.

FIG. 30 illustrates a portion of an example package substrate that includes an example inductor constructed in accordance with teachings disclosed herein

FIG. 31 illustrates a portion of another example package substrate that includes another example inductor constructed in accordance with teachings disclosed herein.

FIG. 32 illustrates a portion of another example package substrate that includes another example inductor constructed in accordance with teachings disclosed herein.

FIG. 33 illustrates a portion of another example package substrate that includes another example inductor constructed in accordance with teachings disclosed herein.

FIG. 34 is a flowchart representative of an example method of manufacturing any one of the example inductors of FIGS. 1-33.

FIG. 35 is a top view of a wafer including dies that may be included in an IC package constructed in accordance with teachings disclosed herein.

FIG. 36 is a cross-sectional side view of an IC device that may be included in an IC package constructed in accordance with teachings disclosed herein.

FIG. 37 is a cross-sectional side view of an IC device assembly that may include an IC package constructed in accordance with teachings disclosed herein.

FIG. 38 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

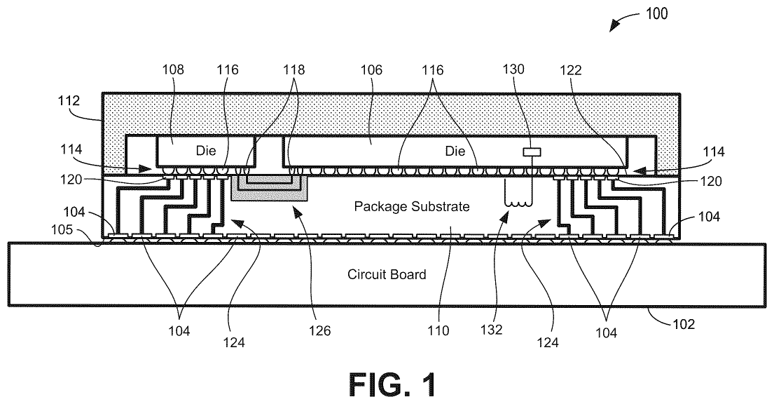

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the landing pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In the illustrated example of FIG. 1, the first die 106 includes a voltage regulator 130 that operates in conjunction with an inductor 132 in the package substrate 110 to manage power provided to other components of the die 106. In some examples, the die 106 is an interposer and the voltage regulator 130 (and the inductor 132) manage power provided to one or more other dies mounted on the interposer. Although one voltage regulator 130 and one inductor 132 are shown in FIG. 1, in other examples, there may be more than one voltage regulator 130 and/or more than one inductor 132. The example inductor 132 is constructed in accordance with teachings disclosed herein. While the example inductors 132 disclosed herein are described for use in conjunction with the voltage regulator 130 shown in FIG. 1, the example inductors disclosed herein may additionally or alternatively be used in any other suitable application.

Integrating a voltage regulator 130 directly into a die (or an interposer supporting a die) provides efficient, fast, and compact power delivery. The performance of the voltage regulator 130 is highly dependent on the performance of the associated inductor(s) 132. A challenge with known implementations of inductors for integrated voltage regulators is the tradeoff of power efficiency and transient performance. For higher power efficiency, the ripple inductance of an inductor needs to be increased. However, for faster transient operations (e.g., turning on and off more quickly), the transient inductance for an inductor needs to be lowered. Past implementations of inductors can achieve only one of these two objectives. For instance, air core inductors (ACIs) are implemented using copper but do not include magnetic materials. Due to space constraints in an IC package, the amount of copper that can be used is limited, thereby resulting in relatively low inductance. This enables fast transient operation but poor voltage conversion efficiency. Another approach that has been developed is inductors that use magnetic material surrounding a central wire or plated through-hole. Such inductors are sometimes referred to as coaxial metal inductor loops. Due to the high permeability of the magnetic materials, coaxial metal inductor loops provide much higher inductance than ACIs within a given (limited) space, thereby achieving greater power efficiency for an associated voltage regulator. However, the higher inductance deteriorates the transient performance of the voltage regulator. Known coaxial metal inductor loops can be altered in their design (e.g., change the plated through-hole core thickness, change the magnetic material used and/or the amount (e.g., volume) of the magnetic material used, etc.) to strike a different balance between efficiency and transient response. However, as one benefit is increased, it will lead to a decrease in the other benefit.

Example inductors disclosed herein can be constructed to achieve both greater power efficiency and faster transient performance than other known techniques for an overall improvement to integrated voltage regulators that rely on such inductors. More particularly, examples disclosed herein involve the implementation of modified coaxial metal inductor loops by embedding multiple separate wires (e.g., multiple plated through-holes) in a given unitary mass of magnetic material (rather than having a single wire in each discrete portion of magnetic material implemented for known coaxial metal inductor loops). In some examples, each wire or plated through-hole of the multiple plated through-holes in a single continuous portion of magnetic material effectively functions as an inductor. However, by providing multiple wires extending through the same portion (e.g., same unitary mass) of magnetic material, the separate wires can become magnetically coupled for increased inductance. Further, inasmuch as the separate wires do not need to be surrounded by discrete (e.g., separate, spaced apart) portions of magnetic material (as in existing techniques), the wires can be placed closer together, thereby increasing inductor density.

Example multi-wire inductors disclosed herein can be constructed with different structures to adjust the tradeoff between power efficiency and transient performance. The differences in structures and available variation in design of the different structures provides greater flexibility in developing inductors suited for different applications relative to known inductor technology. Specifically, a first example structure includes a solid (e.g., continuous) mass of magnetic material that surrounds the separate wires collectively and includes a gap or space within a central region or core of the magnetic material that does not include any magnetic material and that separates adjacent ones of the multiple wires. That is, the magnetic material completely encompasses the wires but does fill the space between the wires. A second example structure includes of the solid (e.g., continuous) mass of the magnetic material surrounding the separate wires collectively and also individually. That is, the magnetic material completely encompasses the wires and also fills in the space between the wires.

Both example structures for multi-wire inductors disclosed herein provide greater ripple inductance (for better power efficiency) and also less transient inductance (for better transient performance) than known, discrete (e.g., single wire) coaxial metal inductor loops. However, the amount of improvement in efficiency and performance of the two structures differs. In particular, the first example structure (with a gap in the magnetic material between the wires) provides a stronger coupling between the wires, resulting in a much smaller transient inductance and a relatively small improvement (e.g., small increase) relative to the ripple inductance relative to known techniques. On the other hand, the second structure (with the magnetic material in the space between the wires) provides a much higher ripple inductance and a relatively small improvement (e.g., small decrease) relative to the transient inductance relative to known techniques. Thus, for applications where the transient performance is of primary concern, the first structure can be selected. By contrast, for applications where power efficiency is of primary concern, the second structure can be selected.

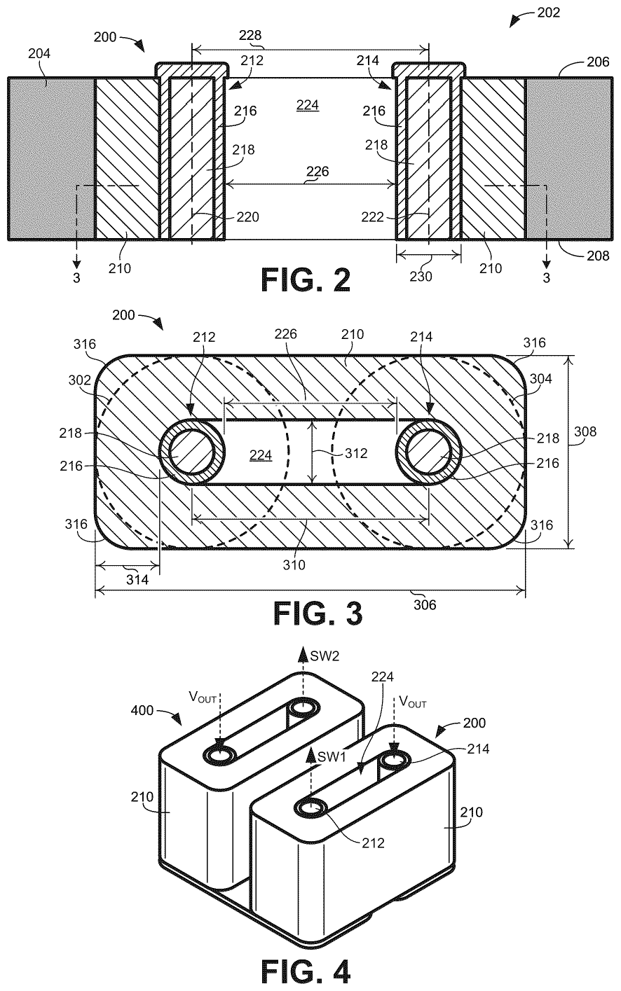

FIG. 2 is a cross-sectional side view of an example inductor 200 within a portion of an example package substrate 202. FIG. 3 is a cross-sectional top view of the example inductor 200 of FIG. 2 taken along the line 3-3 in FIG. 2. FIG. 4 is an isometric view of the example inductor 200 of FIGS. 2 and 3 positioned adjacent to another example inductor 400. In this example, both of the inductors 200, 400 shown in FIG. 4 are similarly constructed. Accordingly, the description of one applies equally to the other.

In some examples, the inductor 200 shown in FIGS. 2-4 corresponds to the inductor 132 of FIG. 1. In some such examples, the package substrate 202 shown in FIG. 2 corresponds to the package substrate 110. As noted above, in the illustrated example of FIG. 2, only a portion of the package substrate 202 is shown. Specifically, in FIG. 2, only a core 204 (e.g., a substrate core) of the package substrate 202 is shown. In some examples, build-up regions including alternating layers of dielectric material and conductive material may be positioned on one or both surfaces 206, 208 of the substrate core 204. In some examples, the conductive material in the build-up regions corresponds to the internal interconnects 124 in the package substrate 110 shown in FIG. 1. The substrate core 204 can be implemented using any suitable material (e.g., organic material, an epoxy, a glass sheet, etc.).

In the illustrated example of FIGS. 2-4, the example inductor 200 includes a magnetic material 210 and first and second plated through-holes 212, 214 (e.g., first and second conductive materials). The magnetic material 210 can be any suitable material with magnetic properties (e.g., iron, alloys containing iron (e.g., silicon steel), ferrites, other ferromagnetic particles or elements, etc.). In this example, the plated through-holes 212, 214 are defined by an outer shell or wall of conductive material 216 (e.g., copper) surrounding an inner core of dielectric material 218 (e.g., epoxy). In some examples, the dielectric material 218 is omitted and the through-holes are filled with the conductive material 216.

As shown in the illustrated example, the magnetic material 210 is disposed within the substrate core 204 and extends through the core 204 between the first and second surfaces 206, 208 of the core 204. Likewise, in this example, the plated through-holes 212, 214 extend through the substrate core 204 between the first and second surfaces 206, 208 along respective axes 220, 222 of the through-holes 212, 214. In this example, the axes 220, 222 are substantially perpendicular to planes defined by the first and second surfaces 206, 208 of the core 204. The through-holes 212, 214 also extend through the magnetic material 210, which surrounds the through-holes 212, 214 so as to separate the through-holes 212, 214 from the material of the substrate core 204. More particularly, in this example, the magnetic material 210 is a single unitary mass such that the magnetic material 210 defines a continuous path completely encompassing both of the plated through-holes 212, 214 in a plane perpendicular to the axis 220, 222 of either one of the through-holes 212, 214 (e.g., a plane parallel to either one of the surfaces 206, 208 of the core 204).

The example inductor 200 of the illustrated example is sometimes referred to as a multi-wire coaxial metal inductor loop. A multi-wire coaxial metal inductor loop is characterized by multiple wires (e.g., the through-holes 212, 214) that extend through a surrounding magnetic material (e.g., the magnetic material 210). In the past, coaxial metal inductor loops have been implemented with a single wire (e.g., a single one of the plated through-holes 212, 214) surrounded by (coaxially aligned with) a discrete portion of magnetic material. In the illustrated example of FIG. 3, the locations of the discrete portions of magnetic material that would surround each individual plated through-holes 212, 214 using past techniques is indicated by the circles 302, 304 shown in dashed lines. Unlike past techniques in which each plated through-hole would have been associated with a separate, discrete portion of magnetic material (e.g., the plated through-holes and the associated magnetic material for each through-hole is physically and electrically decoupled), the example inductor 200 includes two separate wires (e.g., both of the plated through-holes 212, 214) extending through the same, common body (e.g., unitary mass) of magnetic material 210. As a result, the plated through-holes 212, 214 can become magnetically coupled through the magnetic material 210 even though the through-holes 212, 214 may be physically and electrically decoupled. In some examples, each wire (e.g., each plated through-hole 212, 214) functions as an independent inductor. However, the two independent inductors (associated with each individual wire) are magnetically coupled to increase the overall inductance of the system. Although two wires (e.g., two plated through-holes 212, 214) are shown in the illustrated example, in other examples, more than two wires (e.g., more than two plated through-holes) may be implemented in the same, unitary mass of magnetic material to magnetically coupled three or more wires together in a similar manner to the two described herein.

As shown in the illustrated example of FIG. 3, the magnetic material 210 has a generally rectangular cross-sectional shape with a length 306 in a first dimension (generally parallel to a line extending between the plated through-holes 212, 214) and a width 308 in a second dimension (perpendicular to the first dimension). In some examples, the width 308 is approximately 450 micrometers. However, larger and smaller dimensions are possible. As represented in this example, the width 308 corresponds to the size (e.g., diameter) of the circles 302, 304 representative of the discrete portions of magnetic materials used in known inductors. However, in other examples, the width 308 can be less than or greater than the magnetic material used in known inductors. In some examples, the length 306 is approximately 750 micrometers. However, larger and smaller dimensions are possible. The 750 micrometer length 306 noted above is less than the corresponding dimension of two adjacent coaxial inductors implemented in accordance with existing techniques (e.g., based on discrete portions of magnetic material represented by the circles 302, 304). Specifically, the corresponding dimension using existing techniques is approximately 1000 micrometers. In some examples, the length 306 can be less than 1000 micrometers and different than 750 micrometers (e.g., less than 950 micrometers, less than 900 micrometers, less than 800 micrometers, less than 750 micrometers, less than 700 micrometers, etc.).

In the illustrated example of FIGS. 2-4, the inductor 200 includes a region 224 between the plated through-holes 212, 214 that is devoid of the magnetic material 210. That is, in this example, the magnetic material 210 includes a gap or opening (e.g., the region 224) in a central region or area (e.g., a core) of the magnetic material 210 that is positioned between the plated through-holes 212, 214. In some examples, the region 224 (e.g., the gap or opening) extends a full distance 226 between inward facing surfaces of (e.g., closest points on) the plated through-holes 212, 214 such that there is no magnetic material 210 along a line extending from the first plated through-hole 212 to the second plated through-hole 214. Stated differently, in some examples, the region 224 extends continuously from the first plated through-hole 212 to the second plated through-hole 214. In some examples, the region 224 is filled with air. In other examples, the region 224 is filled with some other non-magnetic dielectric material (e.g., any polymeric dielectric such as epoxy based build-up material or the like). In some examples, as shown in FIG. 3, the region 224 has a cross-sectional shape that is generally rectangular with a length 310 extending between the plated through-holes 212, 214 and a width 312 extending perpendicular to the length 310. In this example, the length 310 is greater than the width 312. More particularly, in this example, the length 310 corresponds to a pitch or spacing 228 of the through-holes 212, 214 and the width corresponds to a diameter 230 of the through-holes 212, 214. In other examples, the length 310 of the region 224 can be less than or greater than the pitch 228 of the through-holes 212, 214. Additionally or alternatively, in some examples, the width 312 can be less than or greater than the diameter 230 of the through-holes 212, 214. In some examples, the diameter 230 of the through-holes 212, 214 is approximately 150 micrometers. However, larger and smaller diameters are possible. In some examples, the width 312 of the region 224 is between approximately 50 micrometers and approximately 150 micrometers (e.g., between approximately 80 micrometers and approximately 100 micrometers).

In some examples, the length 310 of the region 224 and/or the corresponding pitch 228 of the through-holes 212, 214 (which are the same in this example) are equal to or less than the width 308 of the magnetic material 210 corresponding to the size (e.g., diameter) of the circles 302, 304 shown in FIG. 3 (indicative of the size of magnetic materials used in known coaxial metal inductor loops). Thus, in some examples, the through-holes 212, 214 are positioned closer together than is possible using existing approaches without having the separate portions of magnetic material (represented by the circles 302, 304) coming into contact or obstructing one another. More particularly, a typical pitch for the plated through-holes using existing techniques is about 550 micrometers. However, in some examples, the pitch 228 of the through-holes 212, 214 is less than approximately 500 micrometers (e.g., less than approximately 450, less than approximately 400, less than approximately 350, less than approximately 300, less than approximately 250, etc.). In some examples, the size, placement, and spacing of the plated through-holes 212, 214 relative to the outer dimensions of the magnetic material 210 are such that a thickness 314 of the magnetic material 210 extending radially outward from the through-holes 212, 214 is at least approximately 150 micrometers. As shown in the illustrated example of FIG. 3, the thickness 314 may be greater at angles extending radially outward from the through-holes 212, 214 toward corners 316 of the rectangular shaped cross-section of the magnetic material 210. That is, as shown in FIG. 3, the magnetic material 210 extends beyond the circles 302, 304 (delineating a consistent radial thickness in all directions) at the corners 316 of the magnetic material 210. In other words, although the corners 316 of the rectangular shape of the magnetic material 210 are rounded, the radius of the rounded corners is less than half the width 308 of the magnetic material 210 (e.g., less than half the diameter of the circles 302, 304). In other examples, the radius of the rounded corners 316 is approximately the same as half the width 308 of the magnetic material 210. In other examples, the corners 316 may be square rather than rounded. Further, in other examples, the magnetic material 210 is not rectangular. That is, the magnetic material 210 can have any suitable shape (e.g., square, circular, oval, hexagonal, diamond, tapered, etc.) Likewise, the central region 224 of the magnetic material 210 does not need to be rectangular, but can be any suitable shape (e.g., square, circular, oval, hexagonal, diamond, tapered, etc.) and/or can define a non-linear (e.g., serpentine, tortuous) path through the magnetic material 210 between the plated through-holes 212, 214.

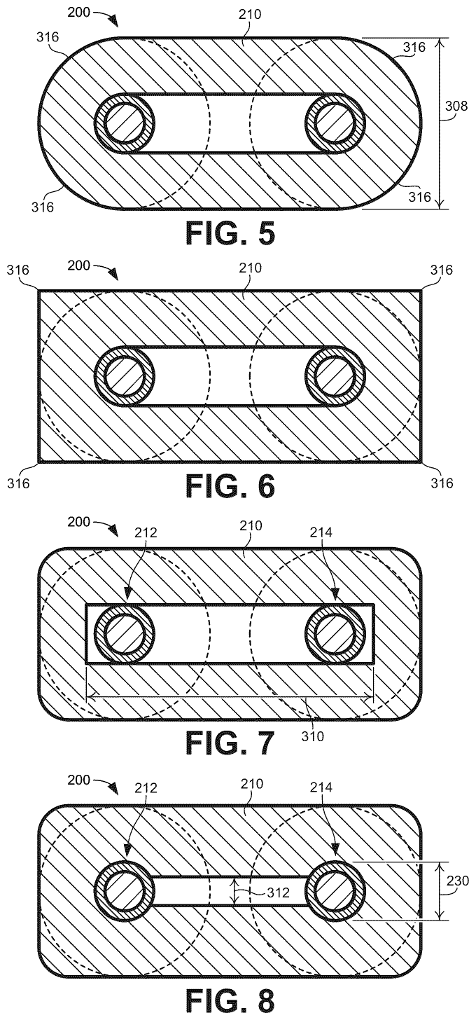

Different example shapes for the magnetic material 210 and the associated region 224 at a center or core of the magnetic material 210 are shown in FIGS. 5-8. Specifically, FIG. 5 shows an alternative implementation of the magnetic material 210 in which the corners 316 have a radius corresponding to half the width 308 of the magnetic material 210. Thus, the entire ends of the magnetic material 210 are rounded to define a generally oval shape for the magnetic material 210. FIG. 6 shows another alternative implementation of the magnetic material 210 in which the corners 316 are square. FIG. 7 shows another alternative implementation of the magnetic material 210 in which the length 310 of the region 224 within the magnetic material 210 extends beyond the outer spacing of the plated through-holes 212, 214. Additionally or alternatively, in some examples, the width of the region 224 extends beyond (e.g., is greater than) the outer diameter of the plated through-holes 212, 214. Thus, in some examples, the magnetic material 210 may not be in direct contact with the through-holes 212, 214. FIG. 8 shows another alternative implementation of the magnetic material 210 in which the width 312 of the region 224 within the magnetic material 210 is less than the diameter 230. The alternative example implementations of the inductor 200 shown in FIGS. 5-8 teach or suggest different features. However, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. Thus, for example, any of the different radii of curvature of the corners 316 can be implemented in combination with any of the different sizes and/or shapes of the central region 224. Further, other example arrangements not explicitly shown may additionally or alternatively be implemented in accordance with teachings disclosed herein.

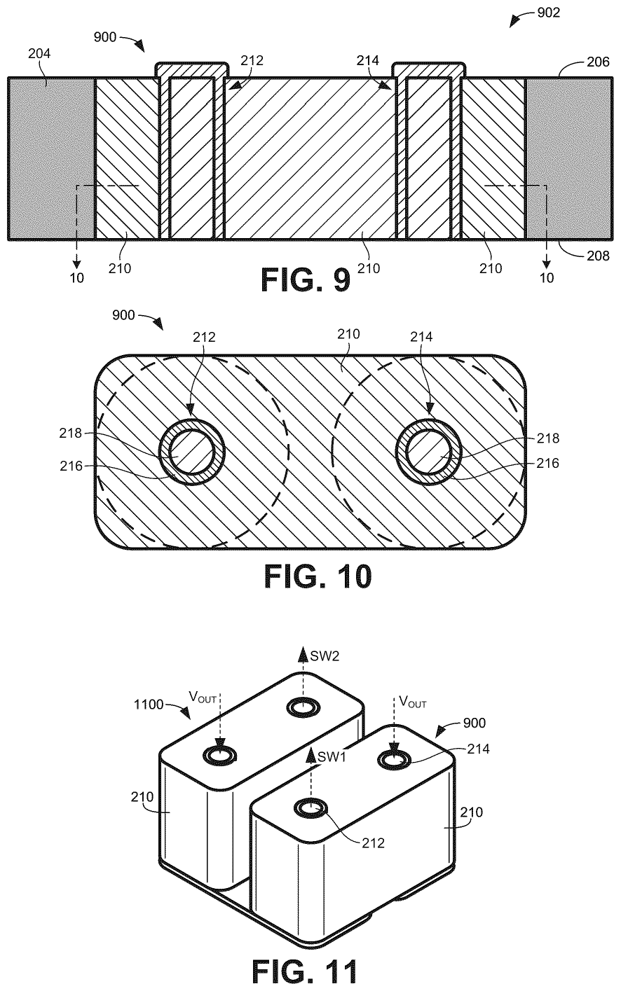

FIG. 9 is a cross-sectional side view of another example inductor 900 within a portion of an example package substrate 902. FIG. 10 is a cross-sectional top view of the example inductor 900 of FIG. 9 taken along the line 10-10 in FIG. 9. FIG. 11 is an isometric view of the example inductor 900 of FIGS. 9 and 10 positioned adjacent to another example inductor 1100. In this example, both of the inductors 900, 1100 shown in FIG. 11 are similarly constructed. Accordingly, the description of one applies equally to the other. Furthermore, the example inductor 900 of FIGS. 9-11 is substantially similar to the example inductor 200 of FIGS. 2-4 except as noted below. Accordingly, the same reference numbers used in FIGS. 2-4 are used for the same and similar components shown in FIGS. 9-11. In some examples, the inductor 900 shown in FIGS. 9-11 corresponds to the inductor 132 of FIG. 1. In some such examples, the package substrate 902 shown in FIG. 9 corresponds to the package substrate 110.

The example inductor 900 of FIGS. 9-11 differs from the example inductor 200 of FIGS. 2-4 in that there is no region 224 in FIG. 9-11 between the plated through-holes 212, 214 devoid of the magnetic material 210. That is, in the illustrated example of FIGS. 9-11, the magnetic material 210 fills the space between the plated through-holes 212, 214. In both the illustrated example of FIGS. 2-4 and the illustrated example of FIGS. 9-11, the magnetic material 210 is in contact with both the first and second plated through-holes 212, 214 as it defines a continuous path completely encompassing both through-holes 212, 214. However, in the illustrated example of FIGS. 9-11, the magnetic material 210 also surrounds or encompasses each of the plated through-holes individually (in addition to encompassing both of them collectively). In other words, the magnetic material 210 is positioned between and separates the plated through-holes 212, 214.

The example inductor 200 of FIGS. 2-4 (and the example variations shown in FIGS. 5-8) represents a first general structure for example inductors disclosed herein characterized by a gap or space within a central region 224 (e.g., core) of the magnetic material 210 that does not include any magnetic material and that separates adjacent ones of the plated through-holes 212, 214. That is, the magnetic material 210 completely encompasses the plated through-holes 212, 214 but does not fill the space between the plated through-holes 212, 214. The example inductor 900 of FIGS. 9-11 represents a second general structure for example inductors disclosed herein characterized by a solid (e.g., continuous) mass of magnetic material 210 that surrounds the separate plated through-holes 212, 214 both collectively and individually. That is, the magnetic material 210 completely encompasses the plated through-holes 212, 214 and also fills in the space between the plated through-holes 212, 214. For purposes of explanation and distinction, the first general structure of the magnetic material 210 is referred to herein as a non-magnetic core structure and the second general structure is referred to herein as a magnetic core structure. The different non-magnetic and magnetic structures provide different benefits and advantages over one another and over previous coaxial metal inductor loops (limited to a single plated through-hole). These advantages and benefits are detailed in Table 1 below, which outlines the coupling coefficient between the two plated through-holes 212, 214 for the two types of structures (magnetic core and non-magnetic core) relative to two adjacent known (single wire) coaxial metal loop inductors (e.g., two inductors having magnetic material in discrete portions defined by the circles 302, 304 of FIG. 3). As used herein, the coupling coefficient can be calculated as the mutual inductance of the two plated through-holes divided by the square root of the product of the self-inductance for each of the two plated through-holes. Table 1 also shows the improvements to the footprint size (which relates to inductance density), the ripple inductance (which relates to power efficiency), and the transient inductance (which relates to transient performance). In Table 1, the values representing these improvements have been normalized by the known coaxial metal inductor loop implementation. The results shown in Table 1 assume the same magnetic material is used in all cases and are based on 1.75V input and 0.8V output conditions.

TABLE I
Performance Comparison

| | Known | Non-Magnetic | Magnetic |
|---|---|---|---|
| | CoaxMIL | Core Structure | Core Structure |
| PTH Pitch | 550 um | 300 um | 300 um |
| Coupling Coefficient | 0.05 | 0.61 | 0.24 |
| Footprint | 1 | 0.75 | 0.75 |
| (Smaller is better) | | | |
| Ripple Inductance | 1 | 1.06 | 1.40 |
| (Larger is better) | | | |
| Transient Inductance | 1 | 0.29 | 0.82 |
| (Smaller is better) | | | |

As can be seen by reference to Table 1, both the magnetic core structure and the non-magnetic core structure provide improvements in both power efficiency (ripple inductance) and performance (transient inductance) relative to the known coaxial metal inductor loop implementation. Moreover, these improvements are achieved within a smaller area and, therefore, also achieve greater inductance density. However, as further outlined in Table 1, the non-magnetic core structure provides a much more significant improvement in performance (transient inductance) than the magnetic core structure. By contrast, the magnetic core structure provides a much more significant improvement in power efficiency (ripple inductance) than the non-magnetic core structure. Thus, the particular type of structure used for a given application may depend on the importance of power efficiency relative to the importance of performance.

Although the example inductor 200 of FIGS. 2-4 and the example variations shown in FIGS. 5-8 (corresponding to the non-magnetic core structure) is distinct from the example inductor 900 of FIGS. 9-11 (corresponding to the magnetic core structure) based on the presence or absence of a central region of the magnetic material 210 being open (e.g., devoid of magnetic material and filled with a dielectric) or filled in (e.g., with a continuous mass of the magnetic material), both types of inductors may be used in combination. That is, in some examples, an IC package (e.g., the IC package 100 of FIG. 1) includes at least one inductor constructed in accordance with FIGS. 2-8 and at least one inductor constructed in accordance with FIGS. 9-11.

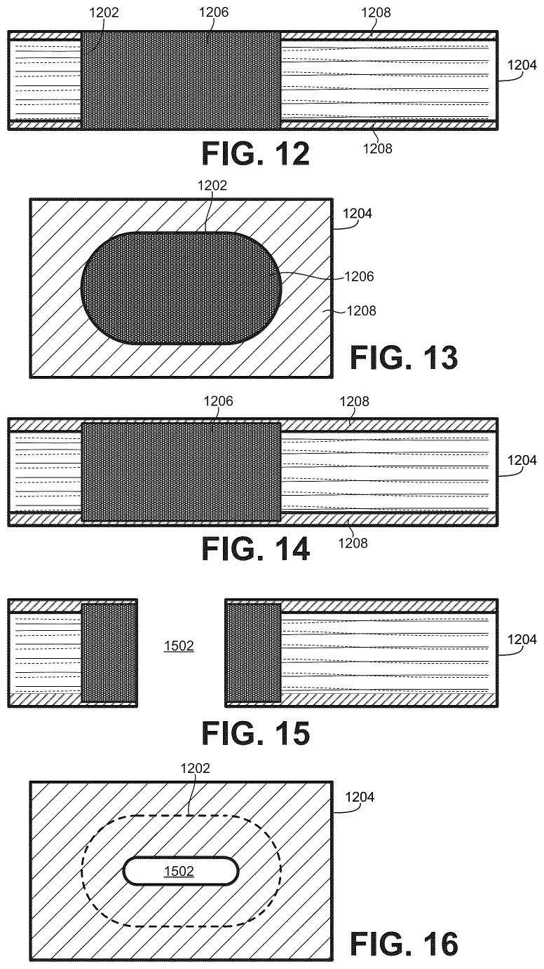

FIGS. 12-25 illustrate different example stages in a fabrication process for the example inductor 200 of FIGS. 2-4 and/or any of the variations detailed in connection with FIGS. 5-8 (e.g., an inductor with an example non-magnetic core structure). FIG. 12 represents the stage in the fabrication process after providing and filling an opening 1202 in a substrate core 1204 with a magnetic paste 1206. In some examples, the substrate core 1204 corresponds to the substrate core 204 of FIG. 2 and the magnetic paste 1206 corresponds to the magnetic material 210 of FIGS. 2-4. In the illustrated example of FIG. 12, the substrate core 1204 includes a layer of conductive material 1208 (e.g., copper) on either side of the substrate core 1204 and the opening extends through the layers of the conductive material 1208. FIG. 13 is a top view of the example substrate core 1204 at the stage of fabrication represented in FIG. 12. As shown in FIG. 13, the opening 1202 (and the magnetic paste 1206 therein) define a generally oval shape similar to the shape of the magnetic material 210 shown in FIG. 5. However, as discussed above, other shapes are possible. In some examples, this shape is created by a router having a diameter corresponding to the width (e.g., the width 308 of FIG. 3) of the opening. In other examples, the opening 1202 can be created by a drill.

FIG. 14 represents the stage in the fabrication process after adding more of the conductive material 1208 to cover the magnetic paste 1206. In some examples, the conductive material 1208 is added through a plating process. In some examples, the thickness of the conductive material 1208 over the magnetic paste 1206 is at least 9 micrometers. FIG. 15 represents the stage in the fabrication process after removing a central region or core of the magnetic paste 1206 to define a notch or gap 1502 that extends through the magnetic paste 1206. In some examples, the notch 1502 is fabricated using a router in a similar manner to the creation of the opening 1202 of FIG. 12. Additionally or alternatively, in some examples, the notch 1502 can be created through a drilling process. FIG. 16 is a top view of the example substrate core 1204 at the stage of fabrication represented in FIG. 15. In FIG. 16, the opening 1202 (corresponding to the outer perimeter of the corresponding magnetic paste 1206) is demarcated by a dashed line.

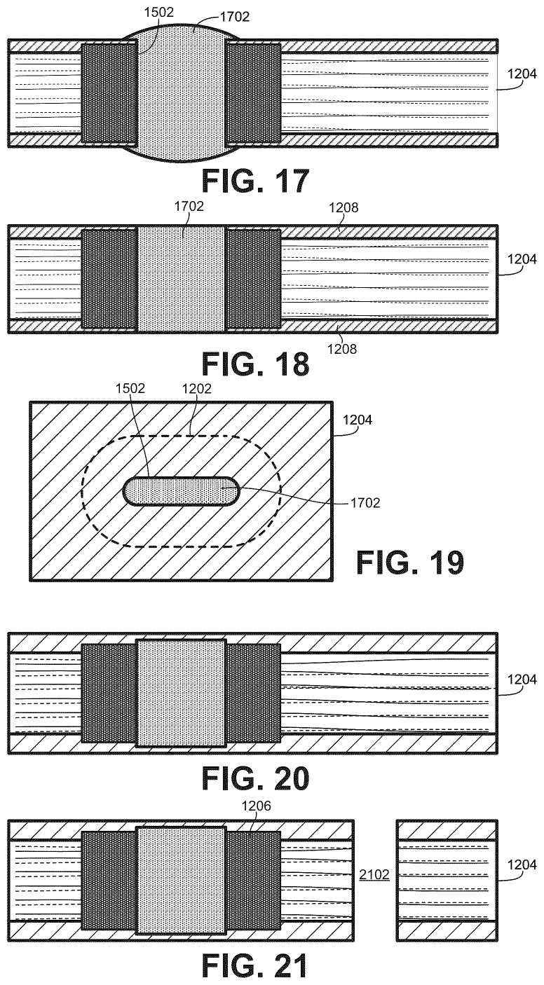

FIG. 17 represents the stage in the fabrication process after filling the notch 1502 with a plug material 1702. In some examples, the plug material 1702 corresponds to a non-magnetic dielectric material that fills the central region 224 shown and described above in connection with FIGS. 2-4. In some examples, when the central region 224 is to be filled with air, the plug material is a sacrificial material that is removed during a subsequent fabrication process. In some examples, the plug material 1702 is deposited within the notch 1502 as a paste and then subsequently cured or hardened.

FIG. 18 represents the stage in the fabrication process after excess portions of the plug material 1702 have been removed. In this manner, the exposed surfaces of the plug material 1702 are generally flat and substantially flush with the layers of conductive layers 1208. In some examples, the excess portions of the plug material 1702 are removed through a grinding process. In some examples, the grinding process is a planarization process that also removes at least some of the conductive material 1208. FIG. 19 is a top view of the example substrate core 1204 at the stage of fabrication represented in FIG. 18. As shown in FIG. 19, the plug material 1702 fills the notch 1502 located in a central region of the magnetic paste 1206 (demarcated by the dashed line defining the walls of the opening 1202).

FIG. 20 represents the stage in the fabrication process after adding more of the conductive material 1208 to cover the plug material 1702. In some examples, the conductive material 1208 is added through a plating process. In some examples, this plating process may be omitted with the plug material 1702 being left exposed.

FIG. 21 represents the stage in the fabrication process after providing a through-hole 2102 through the substrate core 1204 adjacent to the magnetic paste 1206. In some examples, multiple different through-holes 2102 may be provided in the substrate core 1204 at this stage of fabrication through a drilling process. FIG. 22 represents the stage in the fabrication process after providing additional through-holes 2202, 2204 through the magnetic paste 1206. In some examples, the through-holes 2202, 2204 also extend through (e.g., remove a portion of) the plug material 1702. That is, in some examples, the openings of the through-holes 2202, 2204 at least partially overlap or align with the notch 1502 previously provided through the magnetic paste 1206. In some examples, the through-holes 2202, 2204 are provided through a drilling process. In some examples, the through-holes 2202, 2204 of FIG. 22 and the through-hole 2102 of FIG. 21 are provided during a same drilling process. FIG. 23 is a top view of the example substrate core 1204 at the stage of fabrication represented in FIG. 22. In FIG. 23, the notch 1502 is represented by a dashed line (as well as the opening 1202) to show that the notch 1502 (and the corresponding plug material 1702 disposed therein extends the full distance between the through-holes 2202, 2204.

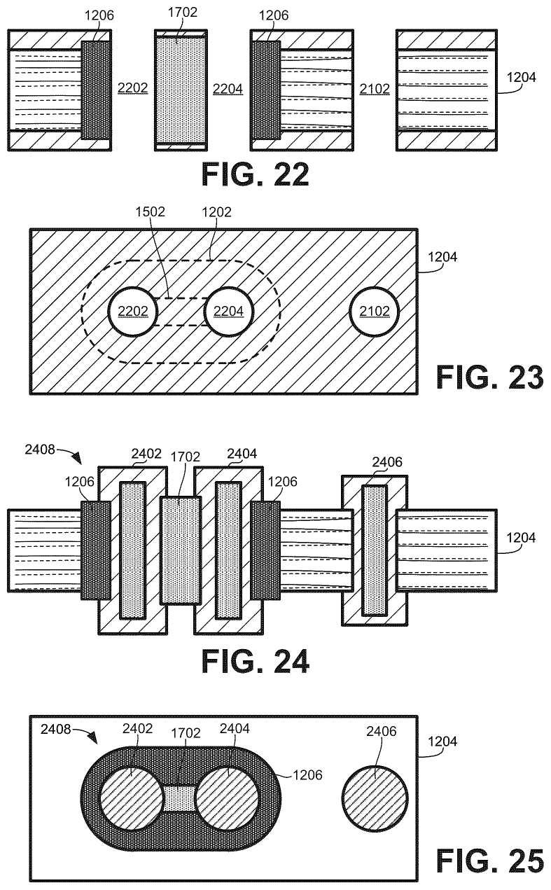

FIG. 24 represents the stage in the fabrication process after the creation of final plated through-holes 2402, 2404, 2406 in respective ones of the through-holes 2102, 2202, 2204 shown in FIGS. 22 and 23. In some examples, the through-holes 2202, 2204 correspond to the first and second plated through-holes 212, 214 of FIGS. 2-4. Further, at the stage of fabrication represented in FIG. 24, the layers of the conductive material 1208 on either side of the substrate core 1204 have been removed (except at the locations of the plated through-holes 2402, 2404, 2406). Thus, each of the plated through-holes 2402, 2404, 2406 are physically and electrically isolated from one another. However, as discussed above, due to the magnetic paste 1206 surrounding the first and second plated through-holes 2402, 2404 (shown most clearly in the top view shown in FIG. 25), the first and second plated through-holes 2402, 2404 are magnetically coupled via the magnetic paste 1206 to improve inductance and define a final structure for an inductor 2408 corresponding to the example inductor 200 of FIGS. 2-4. Following the stage of fabrication represented in FIGS. 24 and 25, further processing may occur to add build-up layers defining electrical interconnects for the plated through-holes 2402, 2404, 2406 and otherwise complete the construction of the corresponding package substrate (e.g., the package substrate 110 of FIG. 1). Further, in some examples, as discussed above, if the central region 224 of the inductor 200 is to be filled with air, the plug material 1702 may be removed using any suitable etching process.

FIGS. 26-28 illustrate different example stages in a fabrication process for the example inductor 900 of FIGS. 9-11 (e.g., an inductor with an example magnetic core structure). Many of the processes shown and described above in FIGS. 12-25 to fabricate the example inductor 200 of FIGS. 2-4 are similar to what would be implemented to fabricate the example inductor 900 of FIGS. 9-11. For instance, in some examples, fabrication processes associated with FIG. 12-14 for a non-magnetic core structure apply equally to the fabrication process for a magnetic core structure. Thus, the same reference numbers are used for the like or same components and the associated fabrication processes discussed above in connection with FIGS. 12-25 apply equally to FIGS. 26-29 except as otherwise noted. In particular, FIG. 26 represents the stage in the fabrication process after having already gone through the operations associated with FIGS. 12-14 (relating to the addition of the magnetic paste 1206 into the substrate core 1204) as well as after the operations associated with FIGS. 21 and 22 (relating to the creation of the through-holes 2102, 2202, 2204). However, in this example, the operations associated with FIGS. 15-20 (relating to the creation of the notch 1502 and the addition of the plug material 1702 disposed therein) are omitted. Thus, as can be seen, FIG. 26 is substantially the same as FIG. 22 except that the space between the through-holes 2202, 2204 in FIG. 26 is filled with the magnetic paste 1206 rather than the plug material 1702 (as in FIG. 22). FIG. 27 is a top view of the example substrate core 1204 at the stage of fabrication represented in FIG. 26. FIG. 27 is substantially the same as FIG. 23 except that, in FIG. 27, there is no demarcated central region corresponding to the notch 1502 because that region corresponds to a continuous unitary mass of the magnetic paste 1206 with the outer perimeter defined by the wall of the opening 1202 (shown in dashed lines).

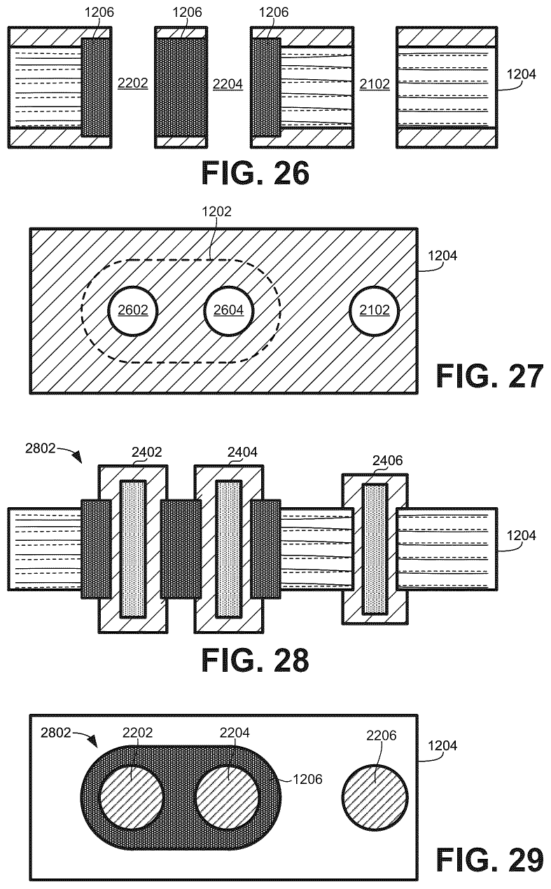

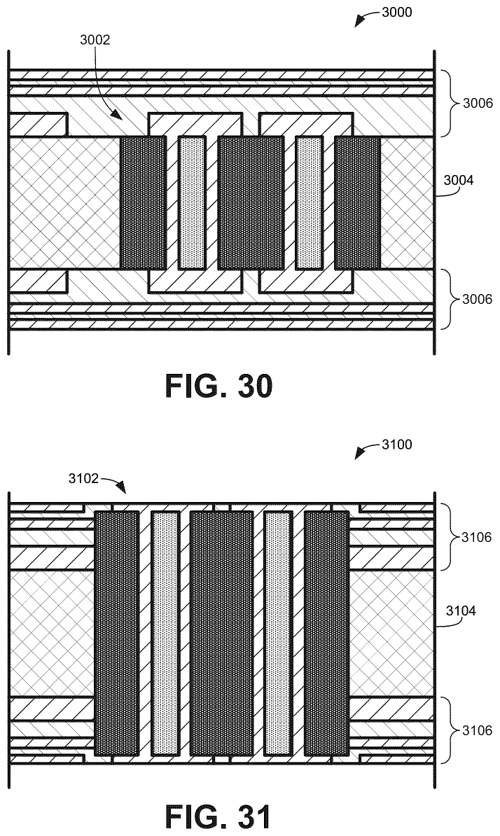

FIGS. 28 and 29 represent the stage in the fabrication process after the same operations involved in arriving at what is shown in FIGS. 24 and 25 discussed above. However, due to the different structure of the magnetic paste 1206 in FIGS. 28 and 29 (e.g., a magnetic core structure) relative to what is shown in FIGS. 24 and 25 (e.g., a non-magnetic core structure), the final plated through-holes 2402, 2404, along the magnetic paste 1206 define a structure for an inductor 2802 corresponding to the example inductor 900 of FIGS. 9-11. Following the stage of fabrication represented in FIGS. 28 and 29, further processing may occur to add build-up layers defining electrical interconnects for the plated through-holes 2402, 2404, 2406 and otherwise complete the construction of the corresponding package substrate (e.g., the package substrate 110 of FIG. 1). For instance, FIG. 30 illustrates a portion of an example package substrate 3000 that includes an example inductor 3002 constructed in accordance with teachings disclosed herein. As shown in FIG. 30, the example inductor 3002 is positioned in and extends through a core 3004 of the package substrate 3000 with build-up regions 3006 provided on either side of the core 3004 (and the associated inductor 3002 embedded therein).

The example inductors 200, 900, 2408, 2802, 3002 (and, more particularly, the magnetic material implemented in such inductors) shown in connection with FIGS. 2-30 extend through and stop at opposite surfaces of a package substrate (e.g., the surface 206, 208 of the substrate core 204 of FIG. 2). However, other arrangements are possible. For instance, FIG. 31 illustrates a portion of another example package substrate 3100 that includes another example inductor 3102 constructed in accordance with teachings disclosed herein. However, unlike the example inductors 200, 900, 2408, 2802, 3002 discussed above, the example inductor 3102 of FIG. 31 extends beyond the surfaces of a core 3104 of the package substrate 3100 and through different layers in build-up regions 3106 provided on either side of the core 3104. In this example, the inductor 3102 extends through the build-up regions 3106 on both sides of the core 3104. However, in other examples, the inductor 3102 may extend beyond only one surface of the core 3104. Additionally or alternatively, in some examples, the inductor 3102 may extend into the build-up regions on opposite sides of the core 3104 by different extents.

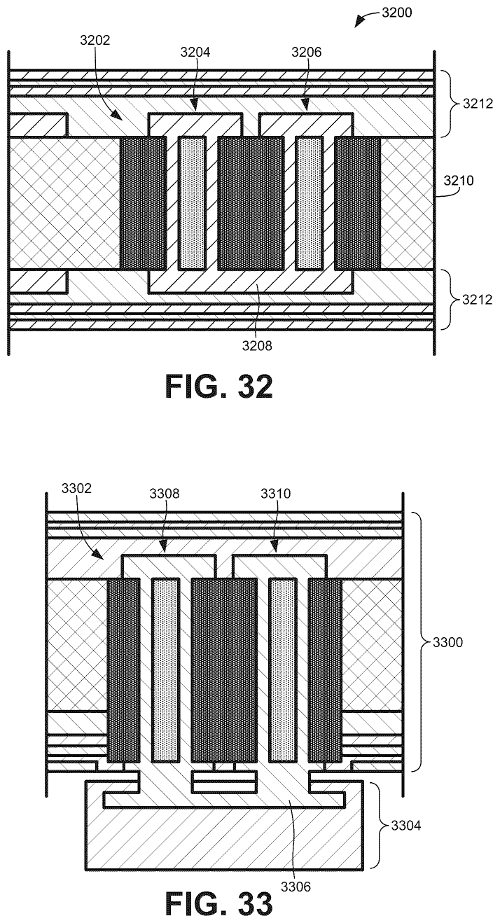

The example inductors 200, 900, 2408, 2802, 3002, 3102 shown in connection with FIGS. 2-31 include plated through-holes that are electrically isolated from one another. However, in some examples, the plated through-holes can be electrically coupled together (in addition to their magnetic coupling). In this manner, separate plated through-holes can be coupled in series to define winding structures for an example inductor. For instance, FIG. 32 illustrates a portion of another example package substrate 3200 that includes another example inductor 3202 constructed in accordance with teachings disclosed herein. The example inductor 3202 of FIG. 32 is substantially the same as the example inductor 3002 of FIG. 30 except that, in FIG. 32, the two magnetically coupled plated through-holes 3204, 3206 of the inductor 3202 are electrical coupled via conductive material 3208 on one side of the substrate core 3210 (e.g., external to the core 3210 and external to the magnetic material in the inductor 3202). In this example, the conductive material 3208 extends along a surface of the substrate core 3210. However, in other examples, the conductive material 3208 electrically coupling the plated through-holes 3204, 3206 can be provided in a different conductive layer in one of the build-up regions 3212.

Additionally or alternatively, in some examples, the plated through-holes may be electrically coupled by a component external to the package substrate 3200. That is, the electrical connection provided between different plated through-holes of example inductors disclosed herein does not need to be on the monolithic substrate but can be connected via other substrates and/or attached semiconductor dies. For instance, FIG. 33 illustrates a portion of another example package substrate 3300 that includes another example inductor 3302 constructed in accordance with teachings disclosed herein. In the illustrated example of FIG. 33, an external component 3304 (e.g., a semiconductor die, a separate package substrate, etc.) is coupled to the package substrate 3300. As shown, the external component 3304 includes a conductive material 3306 (e.g., a trace, an interconnect) that serves to electrical couple the magnetically coupled plated through-holes 3308, 3310 of the inductor 3302.

The foregoing examples of the inductors 132, 200, 900, 2408, 2802, 3002, 3102, 3203, 3302 of FIGS. 1-33 teach or suggest different features. Although each example inductors 132, 200, 900, 2408, 2802, 3002, 3102, 3203, 3302 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

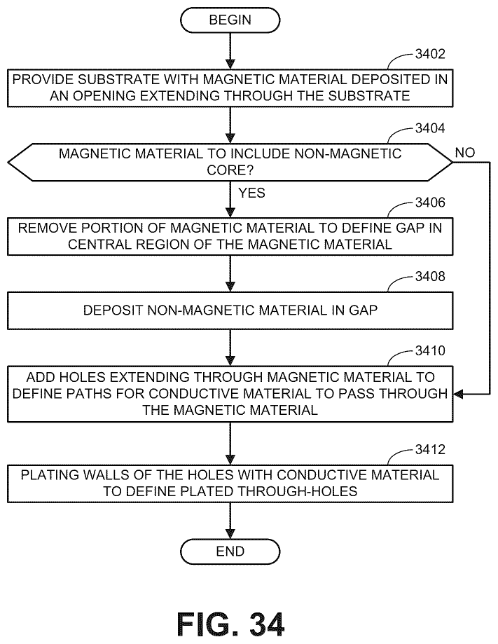

FIG. 34 is a flowchart representative of an example method of manufacturing any one of the example inductors 132, 200, 900, 2408, 2802, 3002, 3102, 3203, 3302 of FIGS. 1-33. In some examples, some or all of the operations outlined in the example method of FIG. 34 are performed automatically by fabrication equipment that is programmed to perform the operations. Although the example method of manufacture is described with reference to the flowchart illustrated in FIG. 34, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example process of FIG. 34 begins at block 3402 by providing a substrate with magnetic material deposited in an opening extending through the substrate. In some examples, block 3402 results in the substrate core 1204 shown in FIGS. 12 and 13. In some examples, the substrate corresponds to the core of a package substrate. In other examples, the substrate can include build-up regions of a package substrate. At block 3404, the process includes determining whether the magnetic material is to include a non-magnetic core. That is, block 3404 determines whether the final inductor is to have a non-magnetic core structure (as in FIGS. 2-8) or a magnetic core structure (as in FIGS. 9-11). If there is to be a non-magnetic core, the example process advances to block 3406 where a portion of the magnetic material is removed to define a gap in the central region of the magnetic material. In some examples, block 3406 results in the substrate core 1204 shown in FIGS. 15 and 16 with the gap corresponding to the notch 1502. At block 3408, the example process includes depositing a non-magnetic material in the gap. In some examples, excess amounts of the non-magnetic material may be removed (e.g., via grinding). In some examples, block 3408 results in the substrate core 1204 shown in FIGS. 18 and 19. Thereafter, control advances to block 3410. Returning to block 3404, if the magnetic material is not to include the non-magnetic core, control advances directly to block 3410.

At block 3410, the example process includes adding holes extending through the magnetic material to define paths for conductive material (e.g., plated through-holes) to pass through the magnetic material. In some examples, at least two holes are provided through a single unitary mass of the magnetic material. In examples where the magnetic material includes a non-magnetic core, the holes are positioned to extend through at least part of the non-magnetic material disposed in the core of the magnetic material. In some such examples, block 3410 results in the substrate core 1204 shown in FIGS. 22 and 23. Where the magnetic material does not include a non-magnetic core, block 3410 results in the substrate core 1204 shown in FIGS. 26 and 27. At block 3412, the example process includes plating walls of the holes with a conductive material to define plated through-holes. Thereafter, the example process of FIG. 34 ends. However, further processing may proceed in accordance with any suitable known and/or later developed fabrication processes.

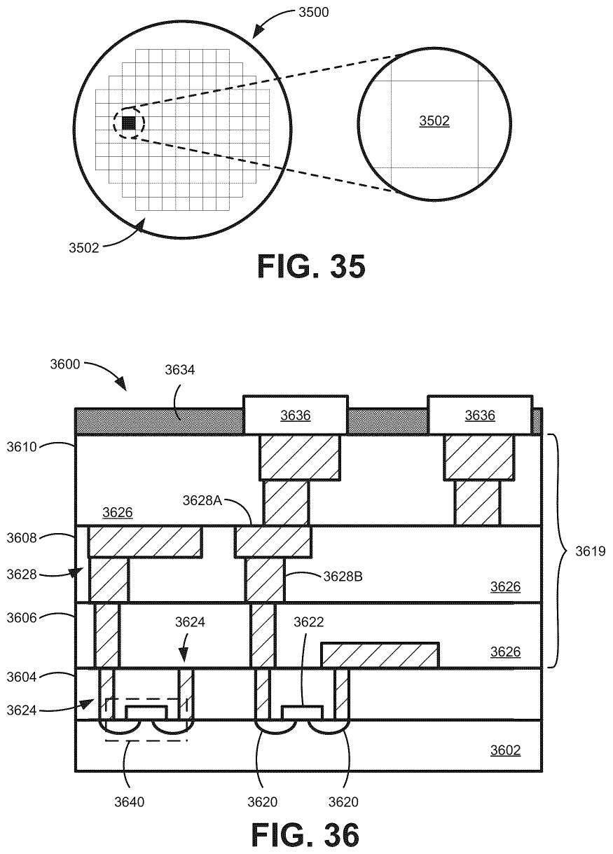

The example inductors 132, 200, 900, 2408, 2802, 3002, 3102, 3203, 3302 disclosed herein may be included in any suitable electronic component. FIGS. 35-38 illustrate various examples of apparatus that may include or be included in the IC package 100 of FIG. 1 containing one or more of the example inductors 132, 200, 900, 2408, 2802, 3002, 3102, 3203, 3302 disclosed herein.

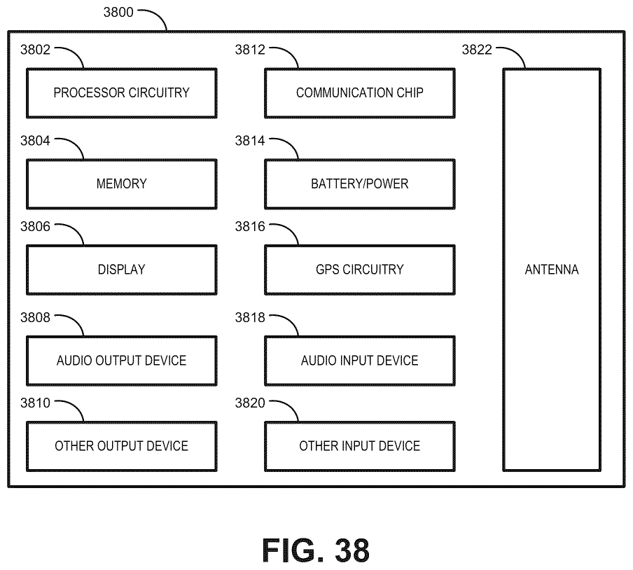

FIG. 35 is a top view of a wafer 3500 and dies 3502 that may be included in the IC package 100 of FIG. 1 (e.g., as any suitable ones of the dies 106, 108). The wafer 3500 may be composed of semiconductor material and may include one or more dies 3502 having circuitry. Each of the dies 3502 may be a repeating unit of a semiconductor product. After the fabrication of the semiconductor product is complete, the wafer 3500 may undergo a singulation process in which the dies 3502 are separated from one another to provide discrete “chips.” The die 3502 may include one or more transistors (e.g., some of the transistors 3640 of FIG. 36, discussed below), supporting circuitry to route electrical signals to the transistors, passive components (e.g., traces, resistors, capacitors, inductors, and/or other circuitry), and/or any other components. In some examples, the die 3502 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 3502. For example, a memory array formed by multiple memory circuits may be formed on a same die 3502 as programmable circuitry (e.g., the processor circuitry 3802 of FIG. 38) or other logic circuitry. Such memory may store information for use by the programmable circuitry. The example IC package 100 disclosed herein may be manufactured using a die-to-wafer assembly technique in which some dies are attached to a wafer 3500 that include others of the dies, and the wafer 3500 is subsequently singulated.

FIG. 36 is a cross-sectional side view of an IC device 3600 that may be included in the example IC package 100 (e.g., in any one of the dies 106, 108). One or more of the IC devices 3600 may be included in one or more dies 3502 (FIG. 35). The IC device 3600 may be formed on a die substrate 3602 (e.g., the wafer 3500 of FIG. 35) and may be included in a die (e.g., the die 3502 of FIG. 35). The die substrate 3602 may be a semiconductor substrate composed of semiconductor material systems including, for example, n-type or p-type materials systems (or a combination of both). The die substrate 3602 may include, for example, a crystalline substrate formed using a bulk silicon or a silicon-on-insulator (SOI) substructure. In some examples, the die substrate 3602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 3602. Although a few examples of materials from which the die substrate 3602 may be formed are described here, any material that may serve as a foundation for an IC device 3600 may be used. The die substrate 3602 may be part of a singulated die (e.g., the dies 3502 of FIG. 35) or a wafer (e.g., the wafer 3500 of FIG. 35).

The IC device 3600 may include one or more device layers 3604 disposed on or above the die substrate 3602. The device layer 3604 may include features of one or more transistors 3640 (e.g., metal oxide semiconductor field-effect transistors (MOSFETs)) formed on the die substrate 3602. The device layer 3604 may include, for example, one or more source and/or drain (S/D) regions 3620, a gate 3622 to control current flow between the S/D regions 3620, and one or more S/D contacts 3624 to route electrical signals to/from the S/D regions 3620. The transistors 3640 may include additional features not depicted for the sake of clarity, such as device isolation regions, gate contacts, and the like. The transistors 3640 are not limited to the type and configuration depicted in FIG. 36 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 3640 may include a gate 3622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 3640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 3640 along the source-channel-drain direction, the gate electrode may consist of a U-shaped structure that includes a bottom portion substantially parallel to the surface of the die substrate 3602 and two sidewall portions that are substantially perpendicular to the top surface of the die substrate 3602. In other examples, at least one of the metal layers that form the gate electrode may simply be a planar layer that is substantially parallel to the top surface of the die substrate 3602 and does not include sidewall portions substantially perpendicular to the top surface of the die substrate 3602. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 3620 may be formed within the die substrate 3602 adjacent to the gate 3622 of each transistor 3640. The S/D regions 3620 may be formed using an implantation/diffusion process or an etching/deposition process, for example. In the former process, dopants such as boron, aluminum, antimony, phosphorous, or arsenic may be ion-implanted into the die substrate 3602 to form the S/D regions 3620. An annealing process that activates the dopants and causes them to diffuse farther into the die substrate 3602 may follow the ion-implantation process. In the latter process, the die substrate 3602 may first be etched to form recesses at the locations of the S/D regions 3620. An epitaxial deposition process may then be carried out to fill the recesses with material that is used to fabricate the S/D regions 3620. In some implementations, the S/D regions 3620 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 3620 may be formed using one or more alternate semiconductor materials such as germanium or a group III-V material or alloy. In further examples, one or more layers of metal and/or metal alloys may be used to form the S/D regions 3620.

Electrical signals, such as power and/or input/output (I/O) signals, may be routed to and/or from the devices (e.g., transistors 3640) of the device layer 3604 through one or more interconnect layers disposed on the device layer 3604 (illustrated in FIG. 36 as interconnect layers 3606-2010). For example, electrically conductive features of the device layer 3604 (e.g., the gate 3622 and the S/D contacts 3624) may be electrically coupled with the interconnect structures 3628 of the interconnect layers 3606-2010. The one or more interconnect layers 3606-2010 may form a metallization stack (also referred to as an “ILD stack”) 3619 of the IC device 3600.

The interconnect structures 3628 may be arranged within the interconnect layers 3606-2010 to route electrical signals according to a wide variety of designs (in particular, the arrangement is not limited to the particular configuration of interconnect structures 3628 depicted in FIG. 36). Although a particular number of interconnect layers 3606-2010 is depicted in FIG. 36, examples of the present disclosure include IC devices having more or fewer interconnect layers than depicted.

In some examples, the interconnect structures 3628 may include lines 3628a and/or vias 3628b filled with an electrically conductive material such as a metal. The lines 3628a may be arranged to route electrical signals in a direction of a plane that is substantially parallel with a surface of the die substrate 3602 upon which the device layer 3604 is formed. For example, the lines 3628a may route electrical signals in a direction in and out of the page from the perspective of FIG. 36. The vias 3628b may be arranged to route electrical signals in a direction of a plane that is substantially perpendicular to the surface of the die substrate 3602 upon which the device layer 3604 is formed. In some examples, the vias 3628b may electrically couple lines 3628a of different interconnect layers 3606-2010 together.

The interconnect layers 3606-2010 may include a dielectric material 3626 disposed between the interconnect structures 3628, as shown in FIG. 36. In some examples, the dielectric material 3626 disposed between the interconnect structures 3628 in different ones of the interconnect layers 3606-2010 may have different compositions; in other examples, the composition of the dielectric material 3626 between different interconnect layers 3606-2010 may be the same.

A first interconnect layer 3606 (referred to as Metal 1 or “M1”) may be formed directly on the device layer 3604. In some examples, the first interconnect layer 3606 may include lines 3628a and/or vias 3628b, as shown. The lines 3628a of the first interconnect layer 3606 may be coupled with contacts (e.g., the S/D contacts 3624) of the device layer 3604.

A second interconnect layer 3608 (referred to as Metal 2 or “M2”) may be formed directly on the first interconnect layer 3606. In some examples, the second interconnect layer 3608 may include vias 3628b to couple the lines 3628a of the second interconnect layer 3608 with the lines 3628a of the first interconnect layer 3606. Although the lines 3628a and the vias 3628b are structurally delineated with a line within each interconnect layer (e.g., within the second interconnect layer 3608) for the sake of clarity, the lines 3628a and the vias 3628b may be structurally and/or materially contiguous (e.g., simultaneously filled during a dual-damascene process) in some examples.

A third interconnect layer 3610 (referred to as Metal 3 or “M3”) (and additional interconnect layers, as desired) may be formed in succession on the second interconnect layer 3608 according to similar techniques and configurations described in connection with the second interconnect layer 3608 or the first interconnect layer 3606. In some examples, the interconnect layers that are “higher up” in the metallization stack 3619 in the IC device 3600 (i.e., further away from the device layer 3604) may be thicker.

The IC device 3600 may include a solder resist material 3634 (e.g., polyimide or similar material) and one or more conductive contacts 3636 formed on the interconnect layers 3606-2010. In FIG. 36, the conductive contacts 3636 are illustrated as taking the form of bond pads. The conductive contacts 3636 may be electrically coupled with the interconnect structures 3628 and configured to route the electrical signals of the transistor(s) 3640 to other external devices. For example, solder bonds may be formed on the one or more conductive contacts 3636 to mechanically and/or electrically couple a chip including the IC device 3600 with another component (e.g., a circuit board). The IC device 3600 may include additional or alternate structures to route the electrical signals from the interconnect layers 3606-2010; for example, the conductive contacts 3636 may include other analogous features (e.g., posts) that route the electrical signals to external components.

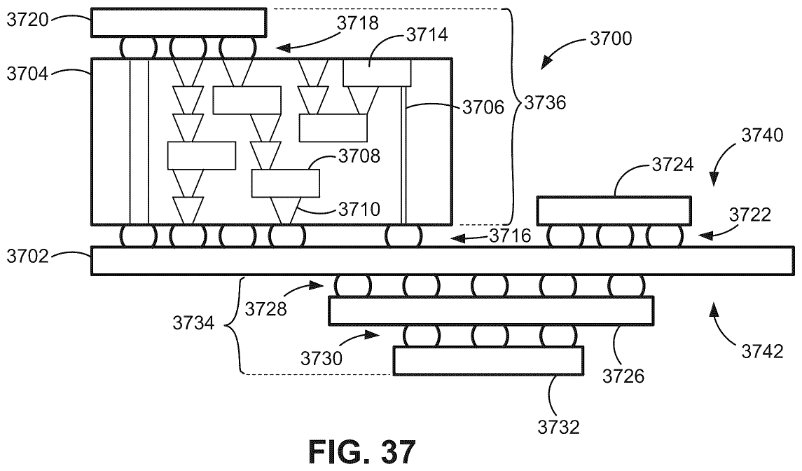

FIG. 37 is a cross-sectional side view of an IC device assembly 3700 that may include the IC package 100 of FIG. 1 and/or one or more example inductors 132, 200, 900, 2408, 2802, 3002, 3102, 3203, 3302 disclosed herein. In some examples, the IC device assembly corresponds to the IC package 100. The IC device assembly 3700 includes a number of components disposed on a circuit board 3702 (which may be, for example, a motherboard). The IC device assembly 3700 includes components disposed on a first face 3740 of the circuit board 3702 and an opposing second face 3742 of the circuit board 3702; generally, components may be disposed on one or both faces 3740 and 3742. Any of the IC packages discussed below with reference to the IC device assembly 3700 may take the form of the example IC package 100 of FIG. 1.

In some examples, the circuit board 3702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 3702. In other examples, the circuit board 3702 may be a non-PCB substrate.

The IC device assembly 3700 illustrated in FIG. 37 includes a package-on-interposer structure 3736 coupled to the first face 3740 of the circuit board 3702 by coupling components 3716. The coupling components 3716 may electrically and mechanically couple the package-on-interposer structure 3736 to the circuit board 3702, and may include solder balls (as shown in FIG. 37), male and female portions of a socket, an adhesive, an underfill material, and/or any other suitable electrical and/or mechanical coupling structure.

The package-on-interposer structure 3736 may include an IC package 3720 coupled to an interposer 3704 by coupling components 3718. The coupling components 3718 may take any suitable form for the application, such as the forms discussed above with reference to the coupling components 3716. Although a single IC package 3720 is shown in FIG. 37, multiple IC packages may be coupled to the interposer 3704; indeed, additional interposers may be coupled to the interposer 3704. The interposer 3704 may provide an intervening substrate used to bridge the circuit board 3702 and the IC package 3720. The IC package 3720 may be or include, for example, a die (the die 3502 of FIG. 35), an IC device (e.g., the IC device 3600 of FIG. 36), or any other suitable component. Generally, the interposer 3704 may spread a connection to a wider pitch or reroute a connection to a different connection. For example, the interposer 3704 may couple the IC package 3720 (e.g., a die) to a set of BGA conductive contacts of the coupling components 3716 for coupling to the circuit board 3702. In the example illustrated in FIG. 37, the IC package 3720 and the circuit board 3702 are attached to opposing sides of the interposer 3704; in other examples, the IC package 3720 and the circuit board 3702 may be attached to a same side of the interposer 3704. In some examples, three or more components may be interconnected by way of the interposer 3704.

In some examples, the interposer 3704 may be formed as a PCB, including multiple metal layers separated from one another by layers of dielectric material and interconnected by electrically conductive vias. In some examples, the interposer 3704 may be formed of an epoxy resin, a fiberglass-reinforced epoxy resin, an epoxy resin with inorganic fillers, a ceramic material, or a polymer material such as polyimide. In some examples, the interposer 3704 may be formed of alternate rigid or flexible materials that may include the same materials described above for use in a semiconductor substrate, such as silicon, germanium, and other group III-V and group IV materials. The interposer 3704 may include metal interconnects 3708 and vias 3710, including but not limited to through-silicon vias (TSVs) 3706. The interposer 3704 may further include embedded devices 3714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3704. The package-on-interposer structure 3736 may take the form of any of the package-on-interposer structures known in the art.

The IC device assembly 3700 may include an IC package 3724 coupled to the first face 3740 of the circuit board 3702 by coupling components 3722. The coupling components 3722 may take the form of any of the examples discussed above with reference to the coupling components 3716, and the IC package 3724 may take the form of any of the examples discussed above with reference to the IC package 3720.

The IC device assembly 3700 illustrated in FIG. 37 includes a package-on-package structure 3734 coupled to the second face 3742 of the circuit board 3702 by coupling components 3728. The package-on-package structure 3734 may include a first IC package 3726 and a second IC package 3732 coupled together by coupling components 3730 such that the first IC package 3726 is disposed between the circuit board 3702 and the second IC package 3732. The coupling components 3728, 3730 may take the form of any of the examples of the coupling components 3716 discussed above, and the IC packages 3726, 3732 may take the form of any of the examples of the IC package 3720 discussed above. The package-on-package structure 3734 may be configured in accordance with any of the package-on-package structures known in the art.

FIG. 38 is a block diagram of an example electrical device 3800 that may include one or more of the example IC package 100 of FIG. 1 and/or one or more example inductors 132, 200, 900, 2408, 2802, 3002, 3102, 3203, 3302. For example, any suitable ones of the components of the electrical device 3800 may include one or more of the device assemblies 3700, IC devices 3600, or dies 3502 disclosed herein, and may be arranged in the example IC package 100. A number of components are illustrated in FIG. 38 as included in the electrical device 3800, but any one or more of these components may be omitted or duplicated, as suitable for the application. In some examples, some or all of the components included in the electrical device 3800 may be attached to one or more motherboards. In some examples, some or all of these components are fabricated onto a single system-on-a-chip (SoC) die.

Additionally, in various examples, the electrical device 3800 may not include one or more of the components illustrated in FIG. 38, but the electrical device 3800 may include interface circuitry for coupling to the one or more components. For example, the electrical device 3800 may not include a display 3806, but may include display interface circuitry (e.g., a connector and driver circuitry) to which a display 3806 may be coupled. In another set of examples, the electrical device 3800 may not include an audio input device 3818 (e.g., microphone) or an audio output device 3808 (e.g., a speaker, a headset, earbuds, etc.), but may include audio input or output device interface circuitry (e.g., connectors and supporting circuitry) to which an audio input device 3818 or audio output device 3808 may be coupled.

The electrical device 3800 may include programmable circuitry 3802 (e.g., one or more processing devices). The programmable circuitry 3802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3800 may include a memory 3804, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 3804 may include memory that shares a die with the programmable circuitry 3802. This memory may be used as cache memory and may include embedded dynamic random access memory (eDRAM) or spin transfer torque magnetic random access memory (STT-MRAM).

In some examples, the electrical device 3800 may include a communication chip 3812 (e.g., one or more communication chips). For example, the communication chip 3812 may be configured for managing wireless communications for the transfer of data to and from the electrical device 3800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3812 may operate in accordance with other wireless protocols in other examples. The electrical device 3800 may include an antenna 3822 to facilitate wireless communications and/or to receive other wireless communications (such as AM or FM radio transmissions).

In some examples, the communication chip 3812 may manage wired communications, such as electrical, optical, or any other suitable communication protocols (e.g., the Ethernet). As noted above, the communication chip 3812 may include multiple communication chips. For instance, a first communication chip 3812 may be dedicated to shorter-range wireless communications such as Wi-Fi or Bluetooth, and a second communication chip 3812 may be dedicated to longer-range wireless communications such as global positioning system (GPS), EDGE, GPRS, CDMA, WiMAX, LTE, EV-DO, or others. In some examples, a first communication chip 3812 may be dedicated to wireless communications, and a second communication chip 3812 may be dedicated to wired communications.

The electrical device 3800 may include battery/power circuitry 3814. The battery/power circuitry 3814 may include one or more energy storage devices (e.g., batteries or capacitors) and/or circuitry for coupling components of the electrical device 3800 to an energy source separate from the electrical device 3800 (e.g., AC line power).

The electrical device 3800 may include a display 3806 (or corresponding interface circuitry, as discussed above). The display 3806 may include any visual indicators, such as a heads-up display, a computer monitor, a projector, a touchscreen display, a liquid crystal display (LCD), a light-emitting diode display, or a flat panel display.

The electrical device 3800 may include an audio output device 3808 (or corresponding interface circuitry, as discussed above). The audio output device 3808 may include any device that generates an audible indicator, such as speakers, headsets, or earbuds.

The electrical device 3800 may include an audio input device 3818 (or corresponding interface circuitry, as discussed above). The audio input device 3818 may include any device that generates a signal representative of a sound, such as microphones, microphone arrays, or digital instruments (e.g., instruments having a musical instrument digital interface (MIDI) output).

The electrical device 3800 may include GPS circuitry 3816. The GPS circuitry 3816 may be in communication with a satellite-based system and may receive a location of the electrical device 3800, as known in the art.

The electrical device 3800 may include any other output device 3810 (or corresponding interface circuitry, as discussed above). Examples of the other output device 3810 may include an audio codec, a video codec, a printer, a wired or wireless transmitter for providing information to other devices, or an additional storage device.

The electrical device 3800 may include any other input device 3820 (or corresponding interface circuitry, as discussed above). Examples of the other input device 3820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3800 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3800 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, apparatus, articles of manufacture, and methods have been disclosed that improve the power efficiency and/or transient performance of inductors relative to known inductor technologies. New structures for coaxial metal inductor loops are disclosed in which multiple plated through-holes are positioned to extend through a unitary mass of magnetic material so that the separate plated through-holes are able to magnetically couple.

Further examples and combinations thereof include the following:

Example 1 includes an apparatus comprising a substrate, first conductive material disposed along a first hole extending through the substrate, second conductive material disposed along a second hole extending through the substrate, and a magnetic material defining a continuous path completely encompassing both the first conductive material and the second conductive material in a plane perpendicular to an axis of the first hole.

Example 2 includes the apparatus of example 1, wherein the magnetic material is in a space between the first conductive material and the second conductive material.

Example 3 includes the apparatus of example 1, further including a region between the first conductive material and the second conductive material that is devoid of the magnetic material.

Example 4 includes the apparatus of example 3, wherein the region is filled with air.

Example 5 includes the apparatus of example 3, wherein the region is filled with a non-magnetic material.

Example 6 includes the apparatus of example 3, wherein the region extends continuously from the first conductive material to the second conductive material.

Example 7 includes the apparatus of example 3, wherein the region has a length in the plane between the first conductive material and the second conductive material, and the region has a width in the plane perpendicular to the length, the length greater than the width.

Example 8 includes the apparatus of example 7, wherein the width is less than a diameter of the first hole.

Example 9 includes the apparatus of example 1, wherein the magnetic material has a length in a first dimension in the plane and a width in a second dimension of the plane, the length greater than the width.

Example 10 includes the apparatus of example 9, wherein the length is less than 900 micrometers.

Example 11 includes the apparatus of example 9, wherein the magnetic material defines a rectangular shape in the plane.

Example 12 includes the apparatus of example 11, wherein the rectangular shape includes rounded corners, a radius of the rounded corners being less than half the width of the magnetic material.

Example 13 includes the apparatus of example 11, wherein the rectangular shape includes rounded corners, a radius of the rounded corners approximately equal to half the width of the magnetic material.

Example 14 includes an integrated circuit package comprising a semiconductor die, and a package substrate to support the die, the package substrate including a core having a first surface and a second surface opposite the first surface, a unitary mass of magnetic material disposed within the core, the magnetic material extending between the first and second surfaces of the core, a first plated through-hole to extend through the unitary mass of the magnetic material, and a second plated through-hole to extend through the unitary mass of the magnetic material, the second plated through-hole spaced apart from the first plated through-hole.

Example 15 includes the integrated circuit package of example 14, further including a conductive material electrically coupling the first and second plated through-holes, the conductive material external to the core and external to the magnetic material.

Example 16 includes the integrated circuit package of example 14, further including a third plated through-hole to extend through the unitary mass of the magnetic material.

Example 17 includes the integrated circuit package of example 14, wherein the first plated through-hole and the second plated through-hole are spaced at a pitch of less than 450 micrometers.

Example 18 includes a method of manufacturing an inductor, the method comprising depositing a magnetic material within an opening in a substrate core, creating a first hole in the magnetic material, creating a second hole in the magnetic material adjacent to and spaced apart from the first hole, and depositing conductive material along walls of the first and second holes.

Example 19 includes the method of example 18, further including removing a central region of the magnetic material to define a gap in the magnetic material prior to creating the first and second holes, the gap to overlap with locations of the first and second holes.

Example 20 includes the method of example 19, further including adding a non-magnetic dielectric material into the gap.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a substrate;
first conductive material disposed along a first hole extending through the substrate;
second conductive material disposed along a second hole extending through the substrate; and
a magnetic material defining a continuous path completely encompassing both the first conductive material and the second conductive material in a plane perpendicular to an axis of the first hole.

2. The apparatus of claim 1, wherein the magnetic material is in a space between the first conductive material and the second conductive material.

3. The apparatus of claim 1, further including a region between the first conductive material and the second conductive material that is devoid of the magnetic material.

4. The apparatus of claim 3, wherein the region is filled with air.

5. The apparatus of claim 3, wherein the region is filled with a non-magnetic material.

6. The apparatus of claim 3, wherein the region extends continuously from the first conductive material to the second conductive material.

7. The apparatus of claim 3, wherein the region has a length in the plane between the first conductive material and the second conductive material, and the region has a width in the plane perpendicular to the length, the length greater than the width.

8. The apparatus of claim 7, wherein the width is less than a diameter of the first hole.

9. The apparatus of claim 1, wherein the magnetic material has a length in a first dimension in the plane and a width in a second dimension of the plane, the length greater than the width.

10. The apparatus of claim 9, wherein the length is less than 900 micrometers.

11. The apparatus of claim 9, wherein the magnetic material defines a rectangular shape in the plane.

12. The apparatus of claim 11, wherein the rectangular shape includes rounded corners, a radius of the rounded corners being less than half the width of the magnetic material.

13. The apparatus of claim 11, wherein the rectangular shape includes rounded corners, a radius of the rounded corners approximately equal to half the width of the magnetic material.

14. An integrated circuit package comprising:
a semiconductor die; and
a package substrate to support the die, the package substrate including:
a core having a first surface and a second surface opposite the first surface;
a unitary mass of magnetic material disposed within the core, the magnetic material extending between the first and second surfaces of the core;
a first plated through-hole to extend through the unitary mass of the magnetic material; and
a second plated through-hole to extend through the unitary mass of the magnetic material, the second plated through-hole spaced apart from the first plated through-hole.

15. The integrated circuit package of claim 14, further including a conductive material electrically coupling the first and second plated through-holes, the conductive material external to the core and external to the magnetic material.

16. The integrated circuit package of claim 14, further including a third plated through-hole to extend through the unitary mass of the magnetic material.

17. The integrated circuit package of claim 14, wherein the first plated through-hole and the second plated through-hole are spaced at a pitch of less than 450 micrometers.

18. A method of manufacturing an inductor, the method comprising:
depositing a magnetic material within an opening in a substrate core;
creating a first hole in the magnetic material;
creating a second hole in the magnetic material adjacent to and spaced apart from the first hole; and
depositing conductive material along walls of the first and second holes.

19. The method of claim 18, further including removing a central region of the magnetic material to define a gap in the magnetic material prior to creating the first and second holes, the gap to overlap with locations of the first and second holes.

20. The method of claim 19, further including adding a non-magnetic dielectric material into the gap.
